(19) United States
(12) Patent Application Publication
(10) Pub. No.: US 2019/0311750 A1
(43) Pub. Date: Oct. 10, 2019

(54) SEMICONDUCTOR APPARATUS

(71) Applicant: SK hynix Inc., Icheon-si Gyeonggi-do (KR)

(72) Inventor: Min Sik HAN, Icheon-si Gyeonggi-do (KR)

(73) Assignee: SK hynix Inc., Icheon-si Gyeonggi-do (KR)

(21) Appl. No.: 16/201,533

(22) Filed: Nov. 27, 2018

(30) Foreign Application Priority Data
Apr. 9, 2018 (KR) 10-2018-0041112

(51) Int. Cl. G11C 7/10

(52) U.S. Cl. CPC G11C 7/1012

(57) ABSTRACT

A semiconductor apparatus may include a plurality of data line sets and a multi-purpose register (MPR) configured to store at least one data set and to output the stored at least one data set as register read data through a first part of the plurality of data line sets. The semiconductor apparatus may also include a data input/output circuit configured to drive the register read data to a driver array to copy the register read data into a second part of the plurality of data line sets, wherein data line sets in the first part of the plurality of data line sets are different from data line sets in the second part of the plurality of data line sets, and wherein the driver array drives the plurality of data line sets during a write operation.

### CROSS-REFERENCES TO RELATED APPLICATION

The present application claims priority under 35 U.S.C. § 119(a) to Korean application number 10-2018-0041112, filed on Apr. 9, 2018, in the Korean Intellectual Property Office, which is incorporated herein by reference in its entirety.

### BACKGROUND

### 1. Technical Field

Various embodiments generally relate to a semiconductor apparatus, and more particularly, to a semiconductor apparatus capable of performing a multi-purpose register read/write operation.

### 2. Related Art

Recently, the operating speed of semiconductor systems including a semiconductor apparatus has been increased with the development of technology related to semiconductor integrated circuits. Therefore, the semiconductor apparatus requires a high-speed data input/output operation.

In order to enhance performance during a high-speed data input/output operation, additional circuits have been gradually added to the semiconductor apparatus.

Examples of the additional circuits may include a multi-purpose register (MPR).

The MPR may be used to support a read leveling operation, for example.

The read leveling operation refers to an operation for transmitting a data pattern pre-defined in a register of a memory chip to a pin set and adjusting a skew of a data strobe signal DQS between the memory chip and a controller for controlling the memory chip.

Therefore, in order to support the read leveling operation, an MPR write operation and MPR read operation are required. The MPR write operation refers to an operation of writing data, for example, the value of a pattern data set to the MPR, and the MPR read operation refers to an operation of reading pattern data stored in the MPR.

### SUMMARY

A semiconductor apparatus in accordance with the present teachings may include a plurality of data line sets and an MPR configured to store at least one data set and to output the stored at least one data set as register read data through a first part of the plurality of data line sets. The semiconductor apparatus may further include a data input/output circuit configured to drive the register read data to a driver array to copy the register read data into a second part of the plurality of data line sets, wherein data line sets in the first part of the plurality of data line sets are different from data line sets in the second part of the plurality of data line sets. The driver array may drive the plurality of data line sets during a write operation.

Another semiconductor apparatus in accordance with the present teachings may include a plurality of data line sets and an MPR configured to store at least one data set and to output the stored at least one data set as register read data through a first part of the plurality of data line sets. The semiconductor apparatus may also include a first data input/output circuit configured to input/output data corresponding to a first portion of a preset data width option and to drive the register read data to a driver array to copy the register read data into a second part of the plurality of data line sets, during a normal operation. The semiconductor apparatus may further include a second data input/output circuit configured to input/output data corresponding to a second portion of the preset data width option, during the normal operation. The driver array of the first data input/output circuit may drive the plurality of data line sets during a write operation. Additionally, data line sets in the first part of the plurality of data line sets are different from data line sets in the second part of the plurality of data line sets, and the first portion of the preset data width option is different from the second portion of the preset data width option.

A further semiconductor apparatus in accordance with the present teachings may include a plurality of memory bank groups arranged in a memory area and a plurality of data line sets coupled to the plurality of memory bank groups. The semiconductor apparatus may also include an MPR, arranged in a first peripheral circuit area and coupled to a first part of the plurality of data line sets, and a first data input/output circuit, arranged in a second peripheral circuit area and coupled to each of the plurality of data line sets. The first data input/output circuit may drive register read data outputted from the MPR to a driver array configured to drive the plurality of data line sets during a write operation to copy the register read data into second part of the plurality of data line sets, wherein data line sets in the first part of the plurality of data line sets are different from data line sets in the second part of the plurality of data line sets.

### BRIEF DESCRIPTION OF THE DRAWINGS

FIG. 1 shows a schematic diagram illustrating a configuration of a semiconductor apparatus, in accordance with an embodiment.

FIG. 2 shows a schematic diagram illustrating a configuration of the first data input/output circuit of FIG. 1, in accordance with an embodiment.

FIG. 3 shows a schematic diagram illustrating a configuration of the first driver of FIG. 2, in accordance with an embodiment.

FIG. 4 shows a schematic diagram illustrating a configuration of the second data input/output circuit of FIG. 1, in accordance with an embodiment.

### DETAILED DESCRIPTION

A semiconductor apparatus according to the present disclosure is described below with reference to the accompanying drawings through exemplary embodiments. For various embodiments, the semiconductor apparatus is capable of performing an MPR operation with a reduced circuit area.

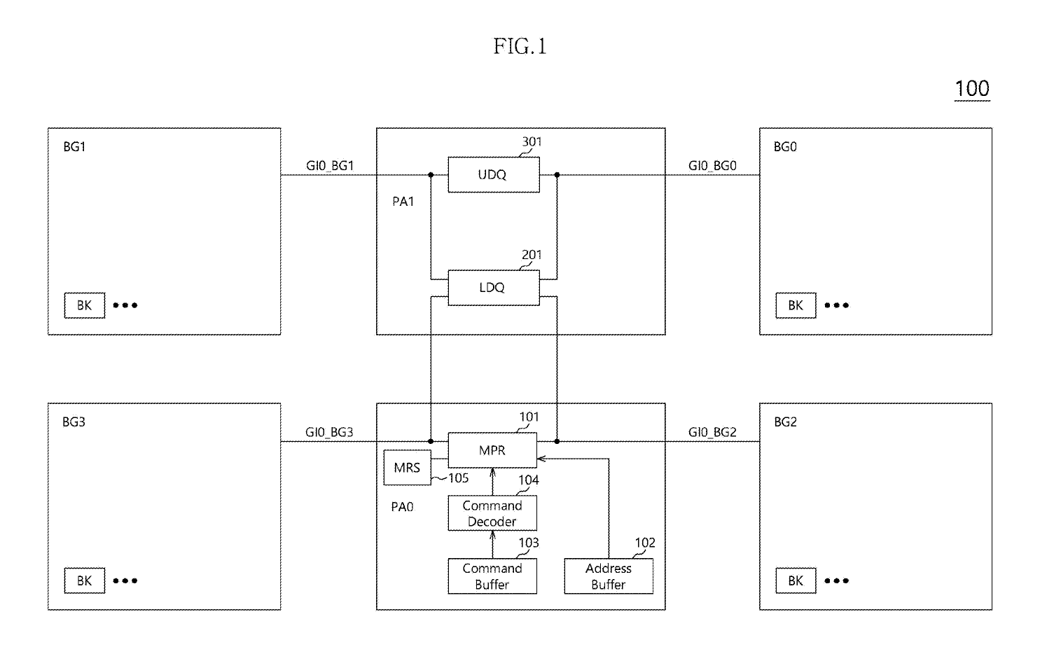

FIG. 1 shows a schematic diagram illustrating a configuration of a semiconductor apparatus 100, in accordance with an embodiment of the present teachings.

As illustrated in FIG. 1, the semiconductor apparatus 100 may include a plurality of memory bank groups BG0, BG1, BG2, and BG3, a first peripheral circuit area PA0, and a second peripheral circuit area PA1.

The area where the plurality of memory bank groups BG0 to BG3 are arranged is defined as a memory area.

Each of the memory bank groups BG0 to BG3 may include a plurality of memory banks BK.

Among the plurality of memory bank groups BG0 to BG3, a first memory bank group BG0 may be coupled to the second peripheral circuit area PA1 through a first data line set GIO_BG0. The word “set,” as used herein, denotes a collection of multiple items for some embodiments and denotes only a single item for other embodiments. Stated differently, a set can have one or more elements.

Among the plurality of memory bank groups BG0 to BG3, a second memory bank group BG1 may be coupled to the second peripheral circuit area PA1 through a second data line set GIO_BG1.

Among the plurality of memory bank groups BG0 to BG3, a third memory bank group BG2 may be coupled to the first peripheral circuit area PA0 and the second peripheral circuit area PA1 through a third data line set GIO_BG2.

Among the plurality of memory bank groups BG0 to BG3, a fourth memory bank group BG3 may be coupled to the first peripheral circuit area PA0 and the second peripheral circuit area PA1 through a fourth data line set GIO_BG3.

The first to fourth data line sets GIO_BG0 to GIO_BG3 may correspond to a global data line GIO.

The first peripheral circuit area PA0 may include a multi-purpose register (MPR) 101, an address buffer 102, a command buffer 103, a command decoder 104, and a mode register set (MRS) 105.

The MPR 101 may perform a register write operation to record data, according to an address and an external command. An external command, for example, might include an MPR write command (hereafter, referred to as a register write command). Data, for example, might include one or more pattern data sets.

The MPR 101 may perform a register read operation to output data sets stored in the MPR 101 as register read data, according to an address and an MPR read command (hereafter, referred to as a register read command).

The register read command may be inputted a plurality of times with predetermined timing differences based on a clock signal, for a training operation, for example.

The MPR 101 may alternately select the third and fourth data line sets GIO_BG2 and GIO_BG3 according to the plurality of register read commands, in order to output the data sets stored therein one by one.

That is, the MPR 101 may output any one set of the data sets stored therein through the third data line set GIO_BG2 according to a first register read command, output another set of the data sets stored therein through the fourth data line set GO_BG3 according to a next register read command, and output another set of the data sets stored therein through the third data line set GO_BG2 according to a next register read command. In this way, the MPR 101 may perform the register read operation by repeating the output process by the input number of register read commands.

The address buffer 102 may receive an external address and provide the received address to the MPR 101.

The command buffer 103 may receive an external command.

The command decoder 104 may generate the register write command or the register read command by decoding an output of the command buffer 103.

The MRS 105 may store various pieces of setting information related to an operation of the semiconductor apparatus 100.

The second peripheral circuit area PA1 may include a first data input/output circuit LDQ 201 and a second data input/output circuit UDQ 301. For some embodiments disclosed herein, “input/output,” also written as “I/O,” refers to input and output. For example, an input/output circuit, or an I/O circuit, represents an input and output circuit.

The first data input/output circuit 201 may be coupled to the first to fourth data line sets GIO_BG0 to GIO_BG3.

The second data input/output circuit 301 may be coupled to the first and second data line sets GIO_BG0 and GIO_BG1.

The first data input/output circuit 201 may input/output data corresponding to half (e.g., 8 bits) of a preset data width option (e.g., X16) during a normal read/write operation.

The first data input/output circuit 201 may drive register read data transmitted through the third and fourth data line sets GIO_BG2 and GIO_BG3 to a driver for driving write data, and may copy the register read data to the first and second data line sets GIO_BG0 and GIO_BG1, according to the register read command. The write data may be inputted through a pad unit described later.

The second data input/output circuit 301 may input/output data corresponding to the other half (e.g., 8 bits) of the preset data width option (e.g., X16) during the normal read/write operation.

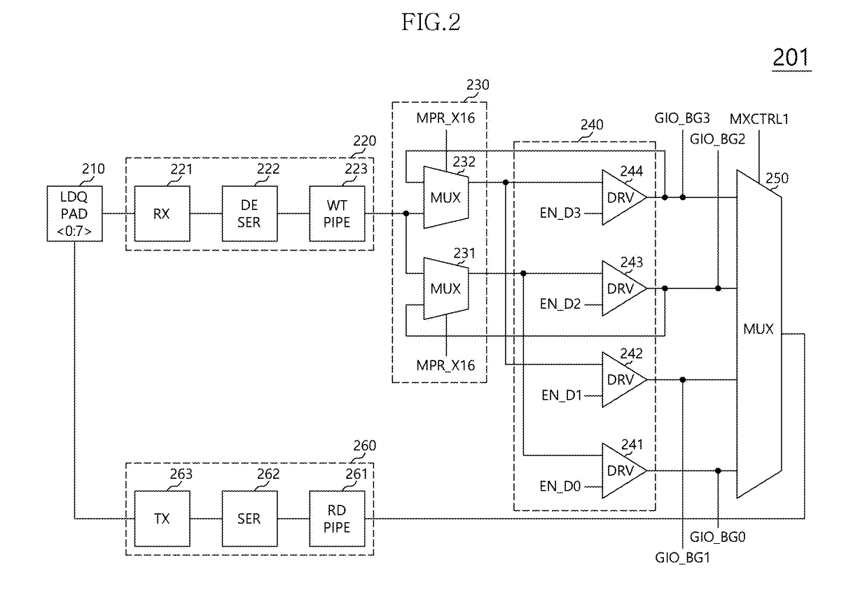

FIG. 2 illustrates a configuration of the first data input/output circuit LDQ 201 of FIG. 1, in accordance with an embodiment.

As illustrated in FIG. 2, the first data input/output circuit 201 may include a pad unit (LDQPAD<0:7>) 210, a write path circuit 220, a first data selection unit 230, a driver array 240, a second data selection unit (MUX) 250, and a read path circuit 260.

The pad unit 210 may include a plurality of input/output pads <0:7>.

The write path circuit 220 may deserialize and latch serial data inputted at a burst length (BL) (e.g., BL=8) set through the pad unit 210.

The write path circuit 220 may include a receiver (RX) 221, a deserializer (DESER) 222, and a write pipe latch (WT PIPE) 223.

The receiver 221 may receive data inputted through the pad unit 210 for a write operation.

The deserializer 222 may deserialize the data received through the receiver 221.

The write pipe latch 223 may latch an output of the deserializer 222.

The first data selection unit 230 may select and output the register read data or an output signal of the write path circuit 220 according to a register data option signal MRP_X16.

The register data option signal MPR_X16 may be activated to a predetermined level (e.g., high level), when the current operation mode is set to the register read operation mode, according to the register read command, and the data width option is set to X16.

The first data selection unit 230 may include first and second multiplexers 231 and 232.

The first multiplexer 231 may select and output the write data transmitted through the write path circuit 220 or the register read data transmitted through the third data line set GIO_BG2, according to the register data option signal MPR_X16.

When the register data option signal MPR_X16 is activated to a high level, for example, the first multiplexer 231 may select and output the register read data transmitted through the third data line set GIO_BG2.

When the register data option signal MPR_X16 is deactivated to a low level, the first multiplexer 231 may select and output the write data transmitted through the write path circuit 220.

The second multiplexer 232 may select and output the write data transmitted through the write path circuit 220 or the register read data transmitted through the fourth data line set GIO_BG3, according to the register data option signal MPR_X16.

The second multiplexer 232 may select and output the register read data transmitted through the fourth data line set GIO_BG3, when the register data option signal MPR_X16 has a level defining the register read operation and the data with option of X16 (for example, high level).

When the register data option signal MPR_X16 is at a low level, the second multiplexer 232 may select and output the data transmitted through the write path circuit 220.

The driver array 240 may be used for the normal write operation, the register write operation, and the register read operation in combination with one another.

The driver array 240 may be basically used for the write operation. In the present embodiment, however, the driver array 240 may be used for the normal write operation, the register write operation, and the register read operation in combination with one another.

The driver array 240 may drive the first to fourth data line sets GIO_BG0 to GIB_BG3 according to a plurality of enable signals EN_D0 to EN_D3 and an output signal of the first data selection unit 230.

The plurality of enable signals EN_D0 to EN_D3 may be selectively activated according to an external address during the normal write operation, and selectively activated according to the setting information or/and the corresponding command (register write command or register read command) during the register write operation and the register read operation.

The setting information may be stored in the MRS 105.

The driver array 240 may include a plurality of drivers, i.e. first to fourth drivers 241 to 244.

The first to fourth drivers 241 to 244 may be configured in the same manner.

The output signal of the first multiplexer 231 may be inputted to the first and third drivers 241 and 243 in common.

The output signal of the second multiplexer 232 may be inputted to the second and fourth drivers 242 and 244 in common.

The first driver 241 may drive the first data line set GIO_BG0 according to the output signal of the first multiplexer 231, when the first enable signal EN_D0 is activated.

The second driver 242 may drive the second data line set GIO_BG1 according to the output signal of the second multiplexer 232, when the second enable signal EN_D1 is activated.

The third driver 243 may drive the third data line set GIO_BG2 according to the output signal of the first multiplexer 231, when the third enable signal EN_D2 is activated.

The fourth driver 244 may drive the fourth data line set GIO_BG3 according to the output signal of the second multiplexer 232, when the fourth enable signal EN_D3 is activated.

The second data selection unit 250 may select and output data transmitted through any one set of the first to fourth line sets GIO_BG0 to GIO_BG3, according to a control signal MXCTRL1.

The control signal MXCTRL1 may have a value for selecting one set of the first to fourth data line sets GIO_BG0 to GIO_BG3 according to an external address (for example, a bank address) which is inputted during a normal read operation of the semiconductor apparatus.

The value of the control signal MXCTRL1 may be varied in such a manner that the third and fourth data line sets GIO_BG2 and GIO_BG3 can be alternately selected according to the register read command during the register read operation of the semiconductor apparatus.

The read path circuit 260 may deserialize the data outputted from the second data selection unit 250 and may output the deserialized data to the pad unit 210.

The read path circuit 260 may include a read pipe latch (RD PIPE) 261, a serializer (SER) 262, and a transmitter (TX) 263.

The read pipe latch 261 may latch the data outputted from the second data selection unit 250.

The serializer 262 may serialize the data latched in the read pipe latch 261.

The transmitter 263 may output the data from the serializer 262 to the pad unit 210.

FIG. 3 illustrates a configuration of the first driver 241 of FIG. 2, in accordance with an embodiment.

As illustrated in FIG. 3, the first driver 241 may include an inverter IV1, a NOR gate NR1, a NAND gate ND1, a first transistor P1, and a second transistor N1.

The inverter IV1 may invert the first enable signal EN_D0 and output the inverted signal.

The NOR gate NR1 may perform a NOR operation on the output signal of the inverter IV1 and an input signal IN, i.e. the output signal of the first multiplexer 231, and output the NOR operation result.

The NAND gate ND1 may perform a NAND operation on the first enable signal EN_D0 and the input signal IN, i.e. the output signal of the first multiplexer 231, and output the NAND operation result.

The first transistor P1 may pull up the first data line set GIO_BG0 to a high voltage VH (for example, VDD) according to the output of the NAND gate ND1.

The second transistor N1 may pull down the first data line set GIO_BG0 to a low voltage VL (for example, VSS or lower level than VDD) according to the output of the NOR gate NR1.

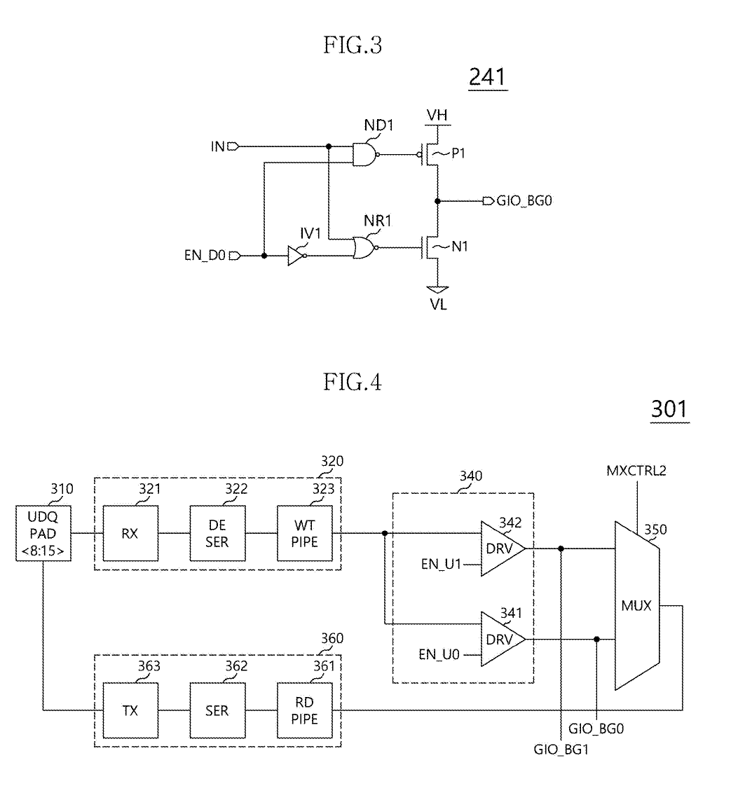

FIG. 4 illustrates a configuration of the second data input/output circuit UDQ 301 of FIG. 1, in accordance with an embodiment.

As illustrated in FIG. 4, the second data input/output circuit 301 may include a pad unit (UDQPAD<8:15>) 310, a write path circuit 320, a driver array 340, a data selection unit (MUX) 350, and a read path circuit 360.

The pad unit 310 may include a plurality of input/output pads <8:15>.

The write path circuit 320 may deserialize and latch serial data inputted at a burst length (BL) (e.g., BL=8) set through the pad unit 310.

The write path circuit 320 may include a receiver (RX) 321, a deserializer (DESER) 322, and a write pipe latch (WT PIPE) 323.

The receiver 321 may receive data inputted through the pad unit 310.

The deserializer 322 may deserialize the data received through the receiver 321.

The write pipe latch 323 may latch an output of the deserializer 322.

The driver array 340 may drive the first and second data line sets GIO_BG0 and GIB_BG1, according to a plurality of enable signals EN_U0 and EN_U1 and an output signal of the write path circuit 320.

The plurality of enable signals EN_U0 and EN_U1 may be selectively activated during the normal write operation and the normal read operation, according to an external address.

The driver array 340 may include a plurality of drivers, i.e. first and second drivers 341 and 342.

The first and second drivers 341 and 342 may be configured in the same manner as described with reference to FIG. 3.

An output signal of the write pipe latch 323 may be inputted to the first and second drivers 341 and 342 in common.

The first driver 341 may drive the first data line set GIO_BG0 according to the output signal of the write pipe latch 323, when the first enable signal EN_U0 is activated.

The second driver 342 may drive the second data line set GIO_BG1 according to the output signal of the write pipe latch 323, when the second enable signal EN_U1 is activated.

The data selection unit 350 may select and output data transmitted through any one set of the first and second line sets GIO_BG0 and GIO_BG1 according to a control signal MXCTRL2.

The control signal MXCTRL2 may have a value for selecting one set of the first and second data line sets GIO_BG0 and GIO_BG1 according to an external address (for example, a bank address), which is inputted during the normal read operation of the semiconductor apparatus 100.

The read path circuit 360 may serialize the data outputted from the data selection unit 350 and output the serialized data to the pad unit 310.

The read path circuit 360 may include a read pipe latch (RD PIPE) 361, a serializer (SER) 362, and a transmitter (TX) 363.

The read pipe latch 361 may latch the data outputted from the data selection unit 350.

The serializer 362 may serialize the data latched in the read pipe latch 361.

The transmitter 363 may output the data from the serializer 362 to the pad unit 310.

In accordance with an embodiment, the register write and read operations of the semiconductor apparatus 100 configured as presented above is described as follows.

First, the register write operation of the semiconductor apparatus 100 is described.

When a register write command is inputted, data sets provided from outside may be outputted through the pad unit 210 and the write path circuit 220 of the first data input/output circuit 201.

Because a register write command is inputted, the register data option signal MPR_X16 may be deactivated to a low level.

Because the register data option signal MPR_X16 is deactivated, the output signal of the write path circuit 220 may be selected through the first or second multiplexer 231 or 232, and inputted to the third or fourth driver 243 or 244.

Assuming that the output signal of the write path circuit 220 is selected through the first multiplexer 231, the third driver 243 may drive the third data line set GIO_BG2 according to an output signal of the first multiplexer 231.

The MPR 101 may record data sets transmitted through the third data line set GIO_BG2.

Next, the register read operation of the semiconductor apparatus 100 is described.

The register read operations may be divided into a case in which the data width option is X8 and a case in which the data width option is X16.

Hereafter, the register read operation in the case where the data width option is X8 is described.

When a register read command is inputted a plurality of times, the MPR 101 may alternately select the third and fourth data line sets GIO_BG2 and GIO_BG3, in order to output data sets stored therein one by one.

Because the data width option is X8, the register data option signal MPR_X16 may be deactivated to a low level.

The data sets which are alternately outputted through the third and fourth data line sets GIO_BG2 and GIO_BG3 may be sequentially selected by the second data selection unit 250 of the first data input/output circuit 201 and may be outputted as the register read data through the pad unit 210 via the read path circuit 260.

Because the data with option is X8, the register read data does not need to be outputted through the pad unit 310 of FIG. 4. Therefore, the second data input/output circuit 301 might not be operated.

Hereafter, the register read operation in the case where the data width option is X16 is described.

When the register read command is inputted a plurality of times, the MPR 101 may alternately select the third and fourth data line sets GIO_BG2 and GIO_BG3, in order to output data sets stored therein one by one.

Because the data width option is X16, the register data option signal MPR_X16 may be activated to a high level.

The data set outputted through the third data line set GIO_BG2 may be selected by the first multiplexer 231 and inputted to the first driver 241, as soon as the data set is inputted to the second data selection unit 250.

The first driver 241 may drive the first data line set GIO_BG0 according to the output of the first multiplexer 231, i.e. the data set outputted through the third data line set GIO_BG2, when the first enable signal EN_D0 is activated.

That is, the data set outputted through the third data line set GIO_BG2 may be driven to the level at which the data set can be transmitted through the first data line GIO_BG0 and copied into the first data line set GIO_BG0 by the first driver 241 configured for the normal read operation.

The data set outputted through the fourth data line set GIO_BG3 may be selected by the second multiplexer 232 and inputted to the second driver 242, as soon as the data set is inputted to the second data selection unit 250.

The second driver 242 may drive the second data line set GIO_BG1 according to the output of the second multiplexer 232, i.e. the data set outputted through the fourth data line set GIO_BG3, when the second enable signal EN_D1 is activated.

That is, the data set outputted through the fourth data line set GIO_BG3 may be driven to the level at which the data set can be transmitted through the second data line GIO_BG1, and copied into the second data line set GIO_BG1 by the second driver 242 configured for the normal read operation.

The data sets which are alternately outputted through the third and fourth data line sets GIO_BG2 and GIO_BG3 may be sequentially selected by the second data selection unit 250 of the first data input/output circuit 201 and may be outputted as 8-bit register read data through the pad unit 210 via the read path circuit 260.

The data sets copied into the first and second data line sets GIO_BG0 and GIO_BG1 may be sequentially selected by the data selection unit 350 of the second data input/output circuit 301 and may be outputted as the other 8-bit register read data through the pad unit 310 via the read path circuit 360.

At this time, the data sets outputted from the MPR 101 may be stably outputted through the pad unit 210 of the first data input/output circuit 201 via the third and fourth data line sets GIO_BG2 and GIO_BG3.

The drivability may be insufficient, for example, when the data sets outputted from the MPR 101 are outputted through the pad unit 310 of the second data input/output circuit 301 via the first and second data line sets GIO_BG0 and GIO_BG1 of the second peripheral circuit area PA1.

In the present embodiment, when the data width option is X16, the semiconductor apparatus can drive the data sets outputted to the third and fourth data line sets GIO_BG2 and GIO_BG3 from the MPR 101, using the driver configured for the write operation without a driver added for the MPR 101, such that the data sets can be transmitted through the first and second data line sets GIO_BG0 and GIO_BG1. Then, the semiconductor apparatus can copy the data sets into the first and second data line sets GIO_BG0 and GIO_BG1.

While various embodiments have been described, it will be understood by those skilled in the art that the described embodiments represent a limited number of possible embodiments consistent with the present teachings. Accordingly, the semiconductor apparatus described herein should not be limited based on the described embodiments.

What is claimed is:

1. A semiconductor apparatus comprising:
a plurality of data line sets;
a multi-purpose register (MPR) configured to store at least one data set and configured to output the stored at least one data set as register read data through a first part of the plurality of data line sets; and
a data input and output (input/output) circuit configured to drive the register read data to a driver array to copy the register read data into a second part of the plurality of data line sets,
wherein data line sets in the first part of the plurality of data line sets are different from data line sets in the second part of the plurality of data line sets, and wherein the driver array drives the plurality of data line sets during a write operation.

2. The semiconductor apparatus according to claim 1, wherein the semiconductor apparatus comprises a plurality of memory bank groups each including a plurality of memory banks, and
wherein each data line set of the plurality of data line sets is coupled to a different memory bank group of the plurality of memory bank groups.

3. The semiconductor apparatus according to claim 1, wherein the
MPR is arranged in a first peripheral circuit area of the semiconductor apparatus, and wherein
the data input/output circuit is arranged in a second peripheral circuit area of the semiconductor apparatus.

4. The semiconductor apparatus according to claim 1 further comprising a mode register set configured to store setting information related to an operation of the semiconductor apparatus,
wherein the data input/output circuit drives the register read data according to the setting information.

5. The semiconductor apparatus according to claim 1, wherein the data input/output circuit comprises:
a pad unit comprising a plurality of input/output pads;
a first data selection unit configured to select and output data inputted through the pad unit or the register read data, according to a register data option signal;
the driver array configured to drive the plurality of data line sets according to the output of the first data selection unit;
a second data selection unit configured to select and output data transmitted through any one set of the plurality of data line sets; and
a read path circuit configured to serialize the data outputted from the second data selection unit and output the serialized data to the pad unit.

6. A semiconductor apparatus comprising:
a plurality of data line sets;
a multi-purpose register (MPR) configured to store at least one data set and configured to output the stored at least one data set as register read data through a first part of the plurality of data line sets;
a first data input and output (input/output) circuit configured to input/output data corresponding to a first portion of a preset data width option and configured to drive the register read data to a driver array to copy the register read data into a second part of the plurality of data line sets, during a normal operation; and
a second data input/output circuit configured to input/output data corresponding to a second portion of the preset data width option, during the normal operation,
wherein data line sets in the first part of the plurality of data line sets are different from data line sets in the second part of the plurality of data line sets, wherein the first portion of the preset data width option is different from the second portion of the preset data width option, and wherein the driver array of the first data input/output circuit drives the plurality of data line sets during a write operation.

7. The semiconductor apparatus according to claim 6, wherein the first data input/output circuit is coupled to the plurality of data line sets, and wherein the second data input/output circuit is coupled to a part of the plurality of data line sets.

8. The semiconductor apparatus according to claim 6, wherein the semiconductor apparatus comprises a plurality of memory bank groups, wherein each memory bank group includes a plurality of memory banks, and wherein each memory bank group is coupled to a different data line set of the plurality of data line sets.

9. The semiconductor apparatus according to claim 6, wherein the
MPR is arranged in a first peripheral circuit area of the semiconductor apparatus, and wherein
the data input/output circuits are arranged in a second peripheral circuit area of the semiconductor apparatus.

10. The semiconductor apparatus according to claim 6, further comprising comprises a mode register set configured to store setting information related to an operation of the semiconductor apparatus,
wherein the data input/output circuits drive the register read data according to the setting information.

11. The semiconductor apparatus according to claim 6, wherein the first data input/output circuit comprises:
a pad unit comprising a plurality of input/output pads;
a first data selection unit configured to select and output data inputted through the pad unit or the register read data according to a register data option signal;
the driver array configured to drive the plurality of data line sets according to the output of the first data selection unit;
a second data selection unit configured to select and output data transmitted through any one set of the plurality of data line sets; and
a read path circuit configured to serialize the data outputted from the second data selection unit, and output the serialized data to the pad unit.

12. The semiconductor apparatus according to claim 6, wherein the second data input/output circuit comprises:
a pad unit comprising a plurality of input/output pads;
a driver array configured to drive the second part of the plurality of data line sets according to data inputted through the pad unit;
a data selection unit configured to select and output a data set transmitted through the second part of the plurality of data line sets; and
a read path circuit configured to serialize the data outputted from the data selection unit and output the serialized data to the pad unit.

13. A semiconductor apparatus comprising:
a plurality of memory bank groups arranged in a memory area;
a plurality of data line sets coupled to the plurality of memory bank groups;
a multi-purpose register (MPR) arranged in a first peripheral circuit area and coupled to a first part of the plurality of data line sets; and
a first data input/output circuit arranged in a second peripheral circuit area and coupled to each of the plurality of data line sets,
wherein data line sets in the first part of the plurality of data line sets are different from data line sets in the second part of the plurality of data line sets, and wherein the first data input/output circuit drives register read data outputted from the MPR to a driver array configured to drive the plurality of data line sets during a write operation to copy the register read data into a second part of the plurality of data line sets.

14. The semiconductor apparatus according to claim 13 further comprising a mode register set configured to store setting information related to an operation of the semiconductor apparatus,
wherein the first data input/output circuit drives the register read data according to the setting information.

15. The semiconductor apparatus according to claim 13, wherein the first data input/output circuit comprises:
a pad unit comprising a plurality of input/output pads;
a first data selection unit configured to select and output data inputted through the pad unit or the register read data according to a register data option signal;
the driver array configured to drive the plurality of data line sets according to the output of the first data selection unit;
a second data selection unit configured to select and output data transmitted through any one set of the plurality of data line sets; and
a read path circuit configured to serialize the data outputted from the second data selection unit, and output the serialized data to the pad unit.

16. The semiconductor apparatus according to claim 13, wherein the first data input/output circuit inputs/outputs data corresponding to a first portion of a preset data width option during a normal operation.

17. The semiconductor apparatus according to claim 16, further comprising a second data input/output circuit configured to input/output data corresponding to a second portion of the data width option during the normal operation, wherein the first portion of the preset data width option is different from the second portion of the preset data width option.

18. The semiconductor apparatus according to claim 17, wherein the second data input/output circuit is coupled to the second part of the plurality of data line sets.

19. The semiconductor apparatus according to claim 17, wherein the second data input/output circuit comprises:
a pad unit comprising a plurality of input/output pads;
a driver array configured to drive the second part of the plurality of data line sets according to data inputted through the pad unit;
a data selection unit configured to select and output a data set transmitted through the second part of the plurality of data line sets; and
a read path circuit configured to serialize the data outputted from the data selection unit, and output the serialized data to the pad unit.
